(19) United States
(12) Patent Application Publication
(10) Pub. No.: US 2005/0011212 A1
(43) Pub. Date: Jan. 20, 2005

(54) Device for cooling housing, areas. components, media and the like

(76) Inventor: Michael-Georg Bistekos, Wien (AT)

Correspondence Address: YOUNG & THOMPSON, 745 SOUTH 23RD STREET, 2ND FLOOR, ARLINGTON, VA, 22202, US

(21) Appl. No.: 10/485,366

(22) PCT Filed: Jul. 22, 2002
(86) PCT No.: PCT/AT02/00216

(30) Foreign Application Priority Data
Jul. 30, 2001 (AT) A 1189/01

(51) Int. Cl. F25D 23/12; H05K 7/20

(52) U.S. Cl. 62/259.2; 361/694; 361/690

(57) ABSTRACT

A device for air conditioning housings areas, components, media and the like, especially for cooling components (3) situated in electric or electronic installations, appliances or the like, by an air or liquid flow. A chamber (1) is provided, which includes at least one adjustable membrane (5) and a group of openings (7) which is arranged at a distance (9) directly in front of a partition wall (2) containing openings (8). An air or liquid flow which is oriented through the openings (8) of the partition wall (2) is caused by the adjustment of the membrane (5) and the difference between the flow behaviour of the suction process and that of the discharge process.

The invention relates to a means for climate-control of housings, spaces, components, media and the like, especially for cooling of components located in electrical and electronic systems and devices, by means of a fluid flow, especially an air or liquid flow.

There is often a requirement for controlling the climate of components or media located in systems, devices, and the like, especially for preventing their overheating and maintaining certain temperature ranges. This applies especially to electrical or electronic components which are located in systems, devices and the like and which can heat up during operation such that their serviceability is adversely affected.

It is known that fans can be provided in systems, devices and the like, by which an air flow is produced by means of which the heat produced in these systems, devices and the like by electrical components is dissipated. The fans however are subject to the disadvantage that their operation produces vibrations in the audible range which can be perceived so strongly as a buzz or whistle that it is extremely disturbing to individuals who are located in the area of the systems, devices and the like or can even cause damage to the hearing of these individuals.

Thus the object of the concrete invention is to devise a generic means by which these disturbing or damaging noises can be prevented or at least greatly diminished.

This is achieved as claimed in the invention by a device with the features of claim 1.

As claimed in the invention, there is a chamber which has at least one adjustable membrane and at least one opening which is provided at a distance in front of the partition with an opening.

By moving or displacing at least one membrane, a fluid, for example air or liquid, is alternately intaken into the chamber and forced out, a flow of air or liquid from one side of the partition to the other being formed by the different flow property of the intake process compared to the expulsion process and depending on the distance between the opening of the chamber and the opening of the partition.

To move or displace at least one membrane for example an electromagnet can be used.

According to one preferred embodiment of the invention the openings of the chamber are made tubular or in the shape of a truncated cone or trumpet-shaped.

According to another preferred embodiment of the invention the diameter of the openings or the mouth of the openings in the partition is greater than the diameter of the openings or the mouth of the openings of the chamber.

For the invention the openings in the partition can be made tubular, in the shape of a truncated cone or trumpet-shaped as well as round or flat or oblong.

According to another preferred embodiment of the invention the partition can be made as the side wall of a housing which encompasses the components to be cooled, by which a fluid flow through the housing is caused. The chamber can be provided inside and outside of the housing.

According to another preferred embodiment of the invention the partition is formed by at least one, preferably several passages which are tubular, in the shape of a truncated cone or trumpet-shaped.

According to another preferred embodiment of the invention, in the chamber there can be two membranes which are assigned to one another and are opposite one another and which can be moved synchronously toward one another or apart from one another.

According to another preferred embodiment the membrane can be formed by one wall part of the chamber which can be moved relative to the adjacent parts of the wall of the chamber, between the adjacent edges of the wall part and the wall of the chamber a gap being formed which forms an opening which is tubular in cross section and which is directly opposite the opening in the partition.

Other preferred embodiments are the subject matter of the other dependent claims.

The invention is detailed below using several embodiments which are shown in the drawings.

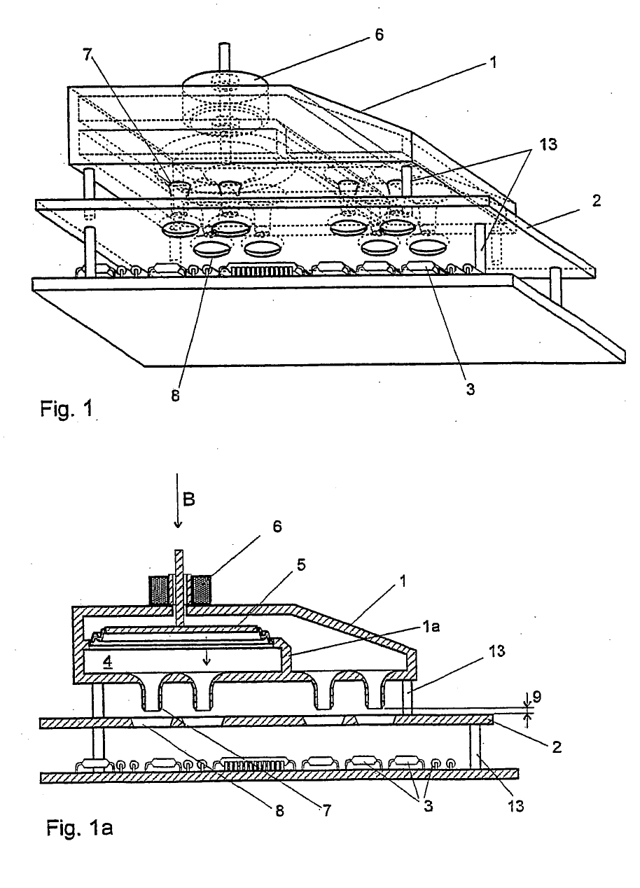

FIG. 1 shows a first embodiment of the means as claimed in the invention in an axonometric representation;

FIG. 1a shows the means as claimed in the invention as shown in FIG. 1 in a section;

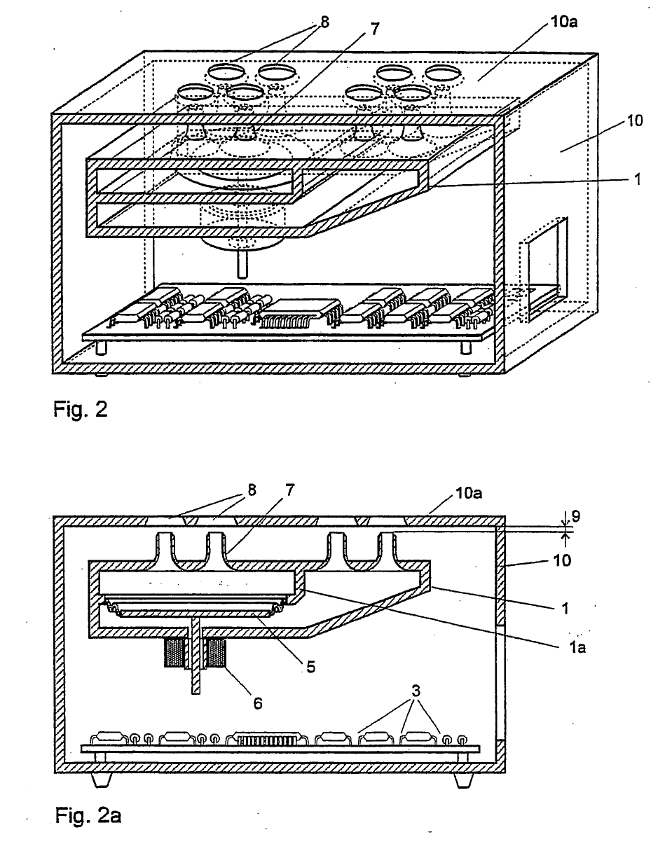

FIG. 2 shows a second embodiment of the means as claimed in the invention in an axonometric representation;

FIG. 2a shows the means as claimed in the invention as shown in FIG. 2 in a section;

FIG. 3 shows a third embodiment of the means as claimed in the invention in a section;

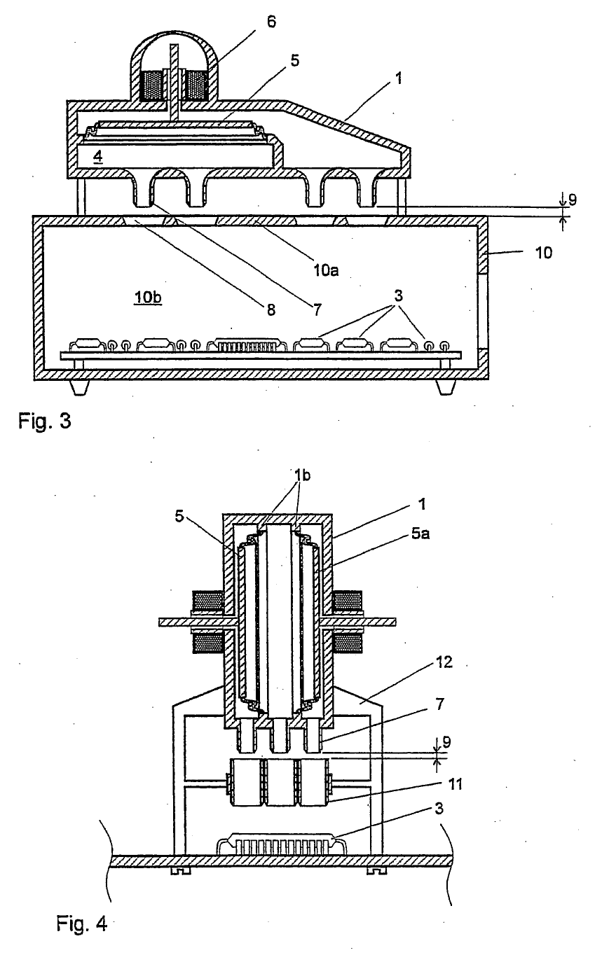

FIG. 4 shows a fourth embodiment of the means as claimed in the invention in a section;

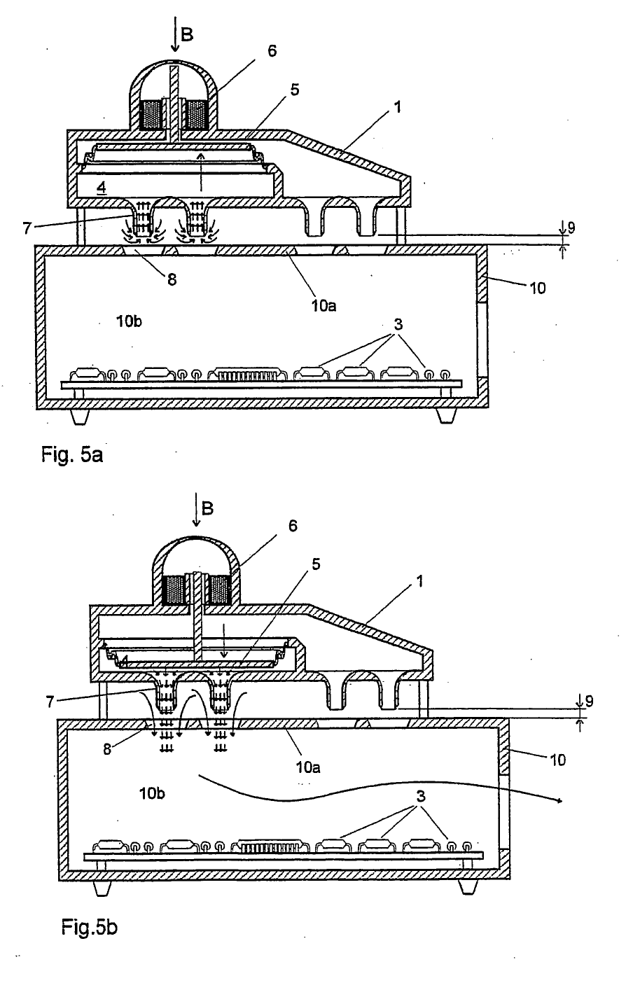

FIGS. 5a and 5b show the means as claimed in the invention as shown in FIG. 3 in two operating positions and in section;

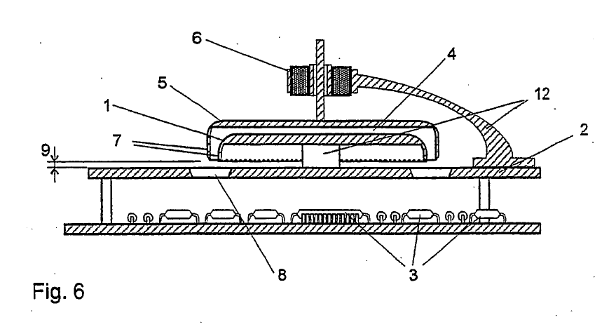

FIG. 6 shows a fifth embodiment of the means as claimed in the invention in a section.

The means as claimed in the invention as shown in FIGS. 1 and 1a consists of a chamber 1, next to which there is a partition 2 and on the other side of which there are electrical or electronic components 3 which must be climate-controlled by means of an air flow, especially cooled.

In the chamber 1 there is an intermediate wall 1a with a membrane 5 which can be moved up and down by means of an electromagnet 6 in and against the direction of the arrow B with a frequency which is below the audio frequency.

In the side wall of the chamber 1 trumpet-shaped holes or openings 7 are made, and in the partition 2, holes or openings 6. The openings 7 are directly opposite the openings 8 at a distance 9. The diameter of the openings 8 of the partition 2 is greater than the diameter of the trumpet-shaped openings 7 of the chamber 1. Furthermore there are support pins 13 which join to one another the chamber 1, the partition 2 and a base plate on which the electrical or electronic components 3 are located.

As soon as the membrane 5 is moved up by means of the electromagnet against the direction of the arrow B, air is intaken into the interior 4 of the chamber 1 through the openings 7. This is shown schematically in FIG. 5a with reference to another embodiment. It can be seen that the air is intaken into the chamber 1 mainly through the gap between the wall of the housing 1 with the openings 7 and the partition 2 or between the facing edges of the openings 7, 8 through the openings 7.

As soon as the membrane 5 is moved down by means of the electromagnet 6 in the direction of the arrow B, air in the form of a directed flow is forced through the openings 8 to the other side of the partition 2 out of the interior 4 of the chamber 1 through the openings 7. This is shown in FIG. 5b. The suction action when being forced out entrains additional air from the gap between the chamber 1 and the partition 2 to the side of the partition 2 facing away from the chamber since the opening 7 which is made as a nozzle in this embodiment acts like an injector. The partition 2 prevents the air which has be conveyed through the opening 8 from flowing back again to a noticeable degree.

Due to the different flow behavior of the intake process in comparison to the expulsion process, a largely continuous flow through the partition 2 in the direction to the electrical or electronic components 3 takes place. The flow behavior can be optimally set according to the respective conditions by the magnitude of the distance 9 or of the gap between the trumpet-shaped openings 7 of the chamber 1 and the openings 8 of the partition 2 which are made larger in cross section.

The air flow causes climate-control, especially cooling, of the electronic components 3 which are located underneath. Since the frequency of the motion of the membrane 5 can be below the audio frequency, for example 15 Hz, audible or disturbing noise is not caused either by the movement of the membrane 5 or by the air flow.

The embodiment as shown in FIGS. 2 and 2a differs from the embodiment as shown in FIGS. 1 and 1a in that the chamber 1 is located within a housing 10 which encompasses the components 3 which are to be cooled, one side wall 10a of the housing being made as a partition. In this way an air flow which passes through the housing 10 is produced, causes climate control of the electrical components 3 located in the interior 10b of the housing 10, and is directed out of the housing 10 on the partition 10a.

The embodiment as shown in FIG. 3 differs from the embodiment as shown in FIGS. 2 and 2a in that the chamber 1 is located outside the housing 10 which encompasses the components 3 to be cooled, again one side wall 10a of the housing being made as a partition. Here an air flow into the interior of the housing 10b is produced and passes through the housing 10, by which climate control of the electrical components 3 which are located in the interior 10b of the housing 10 is caused.

The embodiment as shown in FIG. 4 differs from the existing embodiments among others in that the chamber 1 has two intermediate walls 1b and two membranes 5 and 5a which are opposite one another, the membranes 5 and 5a being moved synchronously toward one another or apart from one another in order to prevent vibration of the chamber 1. The openings 7 of the chamber 1 are made tubular. The partition in the flow-through area is made in the form of tubular channels or passages 11, for each opening 7 of the chamber 1 there being a tubular passage 11. The openings 7 of the chamber 1 and the tubular passages 11 or their edges are located at a distance 9 from one another. Furthermore, there are support arms 12 which join the chamber 1 and the tubular passages 11 to one another. By the movement or vibration of the membranes 5 and 5a an air flow is again produced onto the component 3 which is to be cooled.

In FIGS. 5 and 5a the manner of operation, especially of the embodiment which is also shown in FIG. 3, is shown. The operating principle of the other embodiments of the invention is however corresponding. As soon as the membrane 5 is moved up by means of the electromagnet 6 against the direction of the arrow B, air or liquid is intaken through the trumpet-shaped openings 7 from outside the housing into the interior 4 of the chamber 1. The air is largely intaken from the outside of the housing 10 by the distance 9 of the openings 7 in the housing 1 from the openings 8 in the side wall 10a of the housing 10 which forms the partition.

As soon as the membrane 5 is moved down by means of the electromagnet 6 in the direction of the arrow B, air is forced through the openings 8 to the other side of the side wall 10a, therefore into the housing 10, out of the interior 4 of the chamber 1 through the openings 7. The different flow property or different flow behavior of the intake process compared to the expulsion process and the distance 9 between the trumpet-shaped openings 7 of the chamber 1 and the openings 8 of the side wall 10a of the housing 10, which openings are larger in cross section, cause an air flow through the housing 10. Additional air is entrained into the housing by the suction action which arises when forcing out.

The embodiment as shown in FIG. 6 differs from the other embodiments in that one wall of the chamber 1 is made as a membrane 5. Furthermore there are support arms 12 for the electromagnet 6 and for the immovable part of the chamber 1. The edges of the immovable part of the chamber 1 and of the movable part of the chamber 1 which forms the membrane 5 together form the opening 7 of the chamber 1 in the form of a tubular slot through which air is intaken or forced out. The tubular slot 7 discharges in front of the openings 8 of the partition 2. In place of several openings 8 there can also be only a single annular opening 8 in the partition 2.

1. Means for climate-control of housings, spaces, components, media and the like, especially for cooling of components (3) located in electrical and electronic systems and devices, by means of a fluid flow, especially an air or liquid flow, characterized in that there is a chamber (1) which has at least one movable membrane (5) and at least one opening (7) in the wall of the chamber (1), that the partition (2, 10a) is provided with at least one opening (8), which is directly opposite the opening (8) in the wall of the chamber (1), by the displacement of the membrane (5) a fluid flow being caused through the opening (8) of the partition (2, 10a) by fluid being intaken through a gap (9) between the opening (7) in the wall of the chamber (1) and the opening (8) in the partition (2, 10a) and through the opening (7) in the wall of the chamber (1) into the latter and being forced out of the chamber (1) through the openings (7, 8) of the chamber (1) and the partition (2, 10a).

2. Means as claimed in claim 1, wherein the fluid is intaken through a gap (9) between the wall of the chamber (1) with the opening (7) and the partition (2, 10a) and through the opening (7) of the chamber (1) into the latter and is forced out of the chamber (1) through the openings (7, 8) of the chamber (1) and the partition (2, 10a).

3. Means as claimed in claim 1, wherein there is a group of openings (7) in the wall of the chamber (1) to which is assigned a preferably corresponding number of openings (8) in the partition (2, 10a).

4. Means as claimed in claim 1, wherein a distance (9) is formed between the opposing openings (7) of the chamber (1) and the openings (8) of the partition.

5. Means as claimed in claim 1, wherein the diameter of the openings (8) or the mouth of the openings (8) in the partition (2, 10a) is greater than the diameter of the openings (7) or the mouth of the openings (7) of the chamber.

6. Means as claimed in claim 1, wherein the fluid is intaken through the gap (9) which has been formed between the facing edges of the openings (7, 8) in the wall of the chamber (1) and the partition (2, 10a).

7. Means as claimed in claim 1, wherein the openings (7) of the chamber (1) are made tubular or in the shape of a truncated cone or trumpet-shaped.

8. Means as claimed in claim 7, wherein the openings in the wall of the chamber are formed by tubes which are cylindrical, in the shape of a truncated cone, or trumpet-shaped.

9. Means as claimed in claim 6, wherein the partition (11) is formed by at least one, preferably several passages which are tubular or are in the shape of a truncated cone.

10. Means as claimed in claim 1, wherein the partition is made as a side wall (10a) of a housing (10) which encompasses the components (3) to be cooled.

11. Means as claimed in claim 1, wherein the chamber (1) is divided into two spaces by an intermediate wall (1a), wherein the membrane (5) is located in the intermediate wall and wherein each space has at least one opening (7) to which one opening (8) in the partition (2, 10a) is assigned.

12. Means as claimed in claim 1, wherein in the chamber (1) there are two membranes (5, 5a) which are assigned to one another and are opposite one another and which can be moved synchronously toward one another or apart from one another.

13. Means as claimed in claim 1, wherein the membrane (5) is formed by one wall part of the chamber (1) which can move relative to the adjacent parts of the wall of the chamber (1) and wherein between the adjacent edges (7) of the wall part (5) and the wall of the chamber (1) a gap (9) is formed which forms an opening which is tubular in cross section and which is directly opposite the opening (8) in the partition (2).
